(19) United States
(12) Patent Application Publication
(10) Pub. No.: US 2008/0124855 A1
(43) Pub. Date: May 29, 2008

(54) Modulation of Stress in ESL SiN Film through UV Curing to Enhance both PMOS and NMOS Transistor Performance

(76) Inventors: Johnny Widodo, Singapore (SG); Liu Huang, Singapore (SG)

Correspondence Address: HORIZON IP PTE LTD, 7500A Beach Road, #04-306/308 The Plaza, SINGAPORE 199591, omitted

(21) Appl. No.: 11/556,695

(22) Filed: Nov. 5, 2006

(51) Int. Cl. H01L 21/8238

(52) U.S. Cl. 438/199; 257/E21.632

(57) ABSTRACT

An example embodiment of a method of forming a semiconductor device comprising the following. We form at least a first transistor over a first region of a substrate and forming at least a second transistor over a second region of the substrate. We form a stress layer over the first and second transistors. We form an electromagnetic radiation blocking layer over the second transistor and not over the first transistor. In an exposure step, we expose the electromagnetic radiation blocking layer over the second transistor and exposing the stress layer over the first transistor to electromagnetic radiation to form a cured stress layer over the first transistor. The cured stress layer has a different stress than the stress layer. We may remove the electromagnetic radiation blocking layer.

### BACKGROUND OF INVENTION

1) Field of the Invention

The invention relates generally to fabrication of semiconductor devices using stress inducing films and more particularly to methods for selectively inducing stress in PMOS and NMOS transistors in the manufacture of semiconductor devices.

2) Description of the Prior Art

As semiconductor device switching speeds continue to increase and operating voltage levels continue to decrease, the performance of MOS and other types of transistors needs to be correspondingly improved. The carrier mobility in a MOS transistor has a significant impact on power consumption and switching performance, where improvement in carrier mobility allows faster switching speeds. The carrier mobility is a measure of the average speed of a carrier (e.g., holes or electrons) in a given semiconductor, given by the average drift velocity of the carrier per unit electric field. Improving carrier mobility can improve the switching speed of a MOS transistor, as well as allow operation at lower voltages.

One way of improving carrier mobility involves reducing the channel length and gate dielectric thickness in order to improve current drive and switching performance. However, this approach may increase gate tunneling current, which in turn degrades the performance of the device by increasing off state leakage. In addition, decreasing gate length generally calls for more complicated and costly lithography processing methods and systems.

Other attempts at improving carrier mobility include deposition of silicon/germanium alloy layers between upper and lower silicon layers under compressive stress, which enhances hole carrier mobility in a channel region. However, such buried silicon/germanium channel layer devices have shortcomings, including increased alloy scattering in the channel region that degrades electron mobility, a lack of favorable conduction band offset which may even mitigate the enhancement of electron mobility, and the need for large germanium concentrations to produce strain and thus enhanced mobility.

The use of these additional alloy and silicon layers, moreover, add further processing steps and complexity to the manufacturing process. Furthermore, in CMOS devices, the stress imparted by such a buried silicon/germanium channel layer may adversely affect one type of transistor while improving another. Thus, there remains a need for methods by which the carrier mobility of both NMOS and PMOS transistors may be improved so as to facilitate improved switching speed and low-power, low-voltage operation of CMOS devices, without significantly adding to the cost or complexity of the manufacturing process.

In a relatively newly developed method of enhancing transistor performance, the atomic lattice of a deposited material is stressed to improve the electrical properties of the material itself, or of underlying or overlying material that is strained by the force applied by a stressed deposited material. Lattice strain can increase the carrier mobility of semiconductors, such as silicon, thereby increasing the saturation current of the doped silicon transistors to thereby improve their performance. For example, localized lattice strain can be induced in the channel region of the transistor by the deposition of component materials of the transistor which have internal compressive or tensile stresses. For example, silicon nitride materials used as etch stop materials and spacers for the silicide materials of a gate electrode can be deposited as stressed materials which induce a strain in the channel region of a transistor. The type of stress desirable in the deposited material depends upon the nature of the material being stressed. For example, in CMOS device fabrication, negative-channel (NMOS) doped regions are covered with a tensile stressed material having positive tensile stress; whereas positive channel MOS (PMOS) doped regions are covered with a compressive stressed material having negative stress values.

However, the prior art processes can be further improved.

### SUMMARY OF THE INVENTION

The following presents a simplified summary in order to provide a basic understanding of some aspects of some example embodiments of the invention. This summary is not an extensive overview of the example embodiments or the invention. It is intended neither to identify key or critical elements of the invention nor to delineate the scope of the invention. Rather, the primary purpose of the summary is to present some example concepts of some embodiments of the invention in a simplified form as a prelude to the more detailed description that is presented later.

An example embodiment of a method of forming a semiconductor device comprising the steps of:
forming at least a first transistor over a first region of a substrate and forming at least a second transistor over a second region of the substrate;
forming a stress layer over the first and second type transistors;
forming an electromagnetic radiation blocking layer over the second transistor and not over the first transistor;
in an exposure step, exposing the electromagnetic radiation blocking layer over the second transistor and exposing the stress layer over the first transistor to electromagnetic radiation to form a cured stress layer over the first transistor;
   the cured stress layer has a different stress than the stress layer;
removing the electromagnetic radiation blocking layer.

Another embodiment of the present invention provides a structure and a method of manufacturing a MOS device which is characterized as follows.
forming a NMOS transistor over a NMOS region of a substrate and forming a PMOS transistor over a PMOS region in the substrate; the NMOS transistor has a NMOS channel of the substrate; the PMOS has a PMOS channel in the substrate;
forming a compressive stress layer over the NMOS transistor and PMOS transistor;
forming a UV blocking layer over the PMOS region;
in an exposure step, exposing the compressive stress layer over the NMOS region to ultraviolet light to form a NMOS tensile stress layer over the NMOS region and exposing the UV blocking layer over the PMOS region; the exposure cures the NMOS tensile stress layer to increase the tensile stress; whereby the UV blocking layer blocks the exposure of the compressive stress layer over the PMOS region;
removing the UV blocking layer.

In the example embodiment, a stress layer is formed over PMOS and NMOS devices. An ultra violet (UV) blocking layer is formed over the stress layer over the PMOS devices. We expose the stress layer over the NMOS devices to Ultra Violet (UV) light that to increase the tensile stress in the cured stress layer over the NMOS devices. Preferably the stress layer initially has a compressive stress and after UV exposure, the cured stress layer over the NMOS devices has a tensile stress. The stress layer over the PMOS device preferably maintains it's compressive stress that induces a compressive stress on the PMOS channel.

The above and below advantages and features are of representative embodiments only, and are not exhaustive and/or exclusive. They are presented only to assist in understanding the invention. It should be understood that they are not representative of all the inventions defined by the claims, to be considered limitations on the invention as defined by the claims, or limitations on equivalents to the claims. For instance, some of these advantages may be mutually contradictory, in that they cannot be simultaneously present in a single embodiment. Similarly, some advantages are applicable to one aspect of the invention, and inapplicable to others. Furthermore, certain aspects of the claimed invention have not been discussed herein. However, no inference should be drawn regarding those discussed herein relative to those not discussed herein other than for purposes of space and reducing repetition. Thus, this summary of features and advantages should not be considered dispositive in determining equivalence. Additional features and advantages of the invention will become apparent in the following description, from the drawings, and from the claims.

### BRIEF DESCRIPTION OF THE DRAWINGS

The features and advantages of a semiconductor device according to the present invention and further details of a process of fabricating such a semiconductor device in accordance with the present invention will be more clearly understood from the following description taken in conjunction with the accompanying drawings in which like reference numerals designate similar or corresponding elements, regions and portions and in which:

FIGS. 1 through 5 are cross sectional views for illustrating a method for manufacturing a semiconductor device according to an example embodiment of the present invention.

### DETAILED DESCRIPTION OF THE EXAMPLE EMBODIMENTS

A. Overview

One or more example embodiments of the present invention will now be described with reference to the drawings, wherein like reference numerals are used to refer to like elements throughout, and wherein the various structures are not necessarily drawn to scale. Embodiments relate to methods of producing semiconductor devices with improved transistor carrier mobility, in which the mobility of both NMOS and PMOS transistors may be improved using selectively located differently stressed films, such as a compressive stress film and tensile stress film. Any two different transistors can be formed that perform better using the two different level stress films.

One exemplary implementation of the invention is illustrated and described below, in which the structures illustrated herein are not necessarily drawn to scale.

In this example, PMOS and NMOS devices are shown, but any two different transistors can be formed. The embodiment is not limited to PMOS and NMOS transistors. For example, a first transistor could be a PMOS TX and second transistor could be a PMOS TX with a different configuration or circuit connection.

In the illustrated example, a first stress layer is formed over PMOS and NMOS devices. An electromagnetic radiation or Ultra Violet (UV) blocking coating is formed over the first stress layer over the PMOS devices.

We expose the first stress layer over the NMOS devices to radiation ( e.g. Ultra Violet (UV) light) that increases the tensile stress in the first stress layer over the NMOS. The blocking layer prevents the underlying stress layer from be cured and the stress layer (e.g., compressive) maintains it's stress.

In an aspect, the first stress layer initially has a compressive stress and after exposure, the first stress layer over the NMOS devices has a tensile stress that induces a tensile stress in the NMOS channels. The first stress layer over the PMOS device preferably maintains it's compressive stress to induce a compressive stress on the PMOS channels.

B. NMOS and PMOS Devices

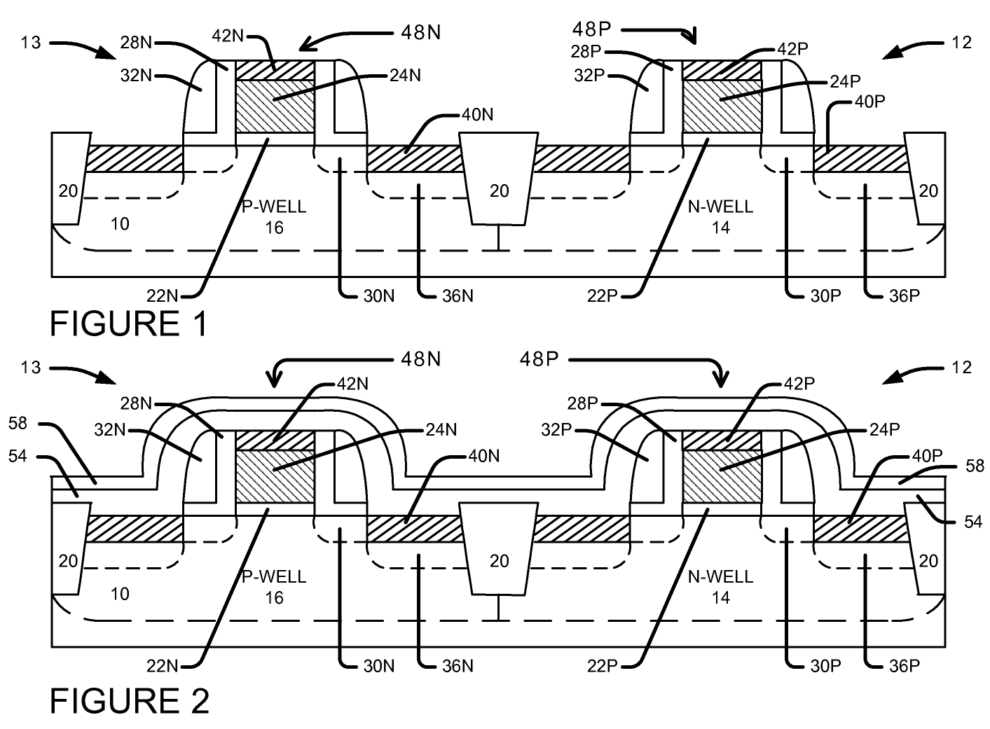

Referring to FIG. 1, we form a NMOS transistor 48N over a NMOS region 13 in a substrate 10 and form a PFET 48P over a PMOS region 12 in the substrate 10. Only two transistor are shown, but many more can be formed. The substrate can be any suitable substrate such as silicon wafer. Isolation regions 20 may separate the NMOS region 13 and the PMOS region 12. These transistors are illustrative and other configurations are possible. Extension regions for can be source drain extensions or LDD region or other extensions types. Note, these FIGS. are not drawn to scale.

The NMOS transistor 48N can be comprised of a NMOS gate dielectric layer 22N, NMOS gate 24N, NMOS gate spacer 28N 32N, NMOS gate silicide 42N, NMOS (e.g., SDE or LDD) extension regions 30N, NMOS S/D regions 36N; and NMOS S/D silicide regions 40N.

The NMOS gate spacer can be formed of 1 or more spacer/liners. The NMOS gate spacer 28N 32N is comprised of a first NMOS spacer 28N and a second NMOS spacer 32N.

The PMOS transistor 48P may be comprised of a PMOS gate dielectric layer 22P, PMOS gate 24P, PMOS gate spacer 28P 32P, PMOS gate silicide 42P, PMOS 30P, (e.g., SDE or LDD) extension regions, PMOS S/D (source and drain) regions 36P; and PMOS S/D silicide regions 40P.

The PMOS gate spacer can be formed of 1 or 2 or more spacer/liners. The PMOS gate spacer 28P 32P can be comprised of a first PMOS spacer 28P and a second PMOS spacer 32P.

The MOS transistors 48N 48P can be comprised of other elements such as Halo regions, etc. The silicide regions 40P 40N may not be a deep as illustrated in the example figures.

C. Stress Layer

Referring to FIG. 2, we form a stress layer 54 (e.g., contact etch-stop layer, stress inducing layer) over the substrate including the NFET 48N and PFET 48P. The stress layer 54 is preferably a compressive stress layer that induces a compressive stress in the channel of the underlying FETs.

The stress layer 54 can be formed of any material whose internal stress is substantially changed by exposure to electromagnetic radiation, such as UV light (UV light can include the wide ranges of UV light include near and far UV light frequencies).

The stress layer can be a PMD high stress SiN etch—stop—layer (ESL) that induces Strain in underlying Si, SiGe or crystalline material.

The compressive stress layer 54 can be comprised of silicon nitride, silicon oxynitride (SiON) or SiCN and preferably consists essentially of silicon nitride.

Different types of stressed materials can be used. One type of stressed material that is commonly deposited comprises silicon nitride. By silicon nitride it is meant a material having silicon-nitrogen (Si—N) bonds, including materials such as silicon oxy-nitride, silicon-oxygen-hydrogen-nitrogen, and other stoichiometric or non-stoichiometric combinations of silicon, nitrogen, oxygen, hydrogen and even carbon. Exemplary methods to deposit silicon nitride stressed material will be described to illustrate the invention; however, it should be understood that these methods can also be used to deposit other types of materials, including stressed silicon oxide, stressed dielectric layers, and others. Thus, the scope of the present invention should not be limited to the illustrative stressed silicon nitride embodiment described herein.

In this example, the compressive stress layer 54 induces a compressive stress on the channel regions of the NFET 48N and the PFET 48P.

An example process for forming the compressive stress layer 54 is comprised of silicon nitride is given in the table below.

TABLE
Example Process Parameter Sets Used for
High Compressive Stresses Levels

| | |
|---|---|
| Temperature | 480° C. |
| SiH₄ | 600 sccm |
| NH₃ | 130 sccm |
| N₂ | 1000 sccm |
| Ar | 3000 sccm |
| HF RF Power | 100 W |
| LF RF Power | 75 W |
| Spacing | 8 mm (325 mils) |
| Pressure | 2 T |
| Dep. Rate | 560 Å/min |
| Uniformity | 2.0%, 1 sigma |
| RI | 1.98 |
| Stress | −2.5 GPa |
| Plasma Stability | Stable |

D. Form a Radiation Blocking Layer Over the PMOS Region

Next, we can form an electromagnetic radiation blocking ((e.g., UV blocking or reflective) layer 58 over the PMOS region. The electromagnetic radiation blocking layer 58 may block between 65 and 100% of any electromagnetic radiation with a wavelength that can substantially reduce or change the tensile stress of a the stress layer.

The electromagnetic radiation blocking layer 58 (such as UV blocking layer 58) may block between about 65% and 100% between 100 and 500 nm and more preferably between about 70% and 100% of the UV light wavelengths between 100 nm and 500 nm.

Preferably the UV blocking (or reflective) layer 58 blocks between about 70% and 100% of the UV light wavelengths between 200 nm and 400 nm.

Referring to FIGS. 2 & 3, we show an example for forming a UV blocking layer 58 (58P) over the PMOS region 12.

As shown in FIG. 2, we form a UV blocking layer 58 over the stress layer 54 over substrate 10.

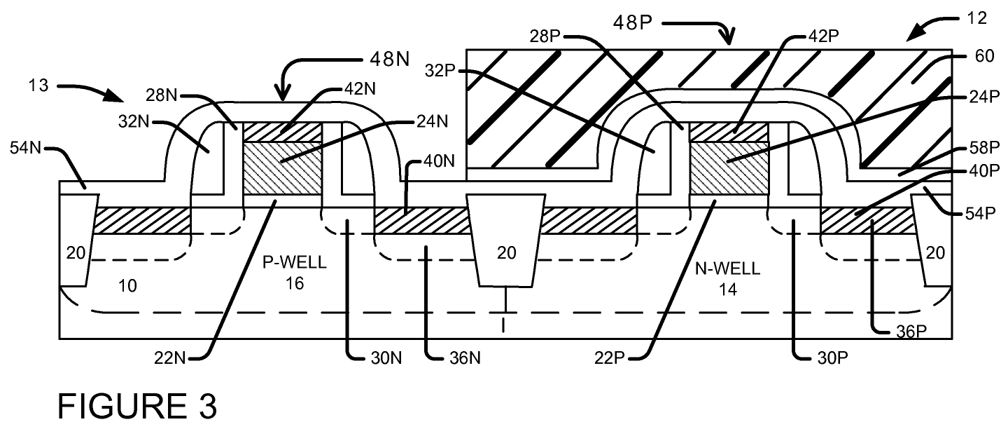

As shown in FIG. 3, we form a PMOS mask 60 over PMOS region 12. The PMOS mask 60 has opening over the NMOS regions 13.

We then remove the UV blocking layer 58 from over the NMOS region 13 using the PMOS mask 60 as an etch mask to leave a PMOS UV blocking layer 58P over the PMOS region 12.

### Electromagnetic Radiation Blocking Layer Comprised of Metal Oxides

The electromagnetic radiation blocking layer 58 can be comprised of a metallic oxide like aluminum oxide (e.g., Al2O3), zinc oxide (ZnO), titanium oxide (TiO2) or their combinations or alloys.

The electromagnetic radiation blocking layer 58 may consist essentially of metallic oxide like aluminum oxide (e.g., Al₂O₃), zinc oxide (e.g., ZnO), titanium oxide (e.g., TiO2) or their alloys or combinations.

In a option, the blocking layer can consist of two of the following materials can be used aluminum oxide (e.g., Al₂O₃), zinc oxide (e.g., ZnO), titanium oxide (e.g., TiO2) where preferably the two materials have a wt % between 30 and 70%.

In an option, the blocking layer can essentially consist of titanium oxide.

An effective amount of suitable material (e.g., an effective amount) may be used that can allow the block layer 58 to block between about 70% and 100% of the UV light wavelengths between about 100 nm and 500 nm and more preferably light wavelengths between about 200 nm and 400 nm.

The blocking layer 58 that is comprised of a metallic oxide(s) like aluminum oxide (Al₂O₃ ), ZnO, or TiO2 and can preferably have a thickness between 50 and 100 angstroms.

UV blocking layers 58 comprised of aluminum oxide, ZnO, TiO2 or their alloys or mixture/combinations can be formed using atomic layer deposition (ALD) techniques

The blocking layer may consist essentially of light blocking materials, such as the inorganic and organic blocking materials listed below. The blocking layer can contain other (e.g., non-light blocking) materials, but this may not be preferable. For the compositions listed below, these wt % preferably refer to light blocking material component in the blocking layer.

The light blocking layer 58 can be comprised of one or more of the blocking materials aluminum oxide (e.g., Al₂O₃) , zinc oxide( e.g., ZnO) and titanium oxide (e.g., TiO₂).

The light blocking layer 58 can be a mixture or alloy of the blocking materials A;2O3, ZnO and TiO2 with a composition of blocking material in the blocking layer that ranges between about 20 to 40% for each compound.

### Blocking Layer Can be Comprised of Organic Materials

The blocking layer 58 may be comprised of one or more organic blocking material(s) such as methoxycinnamate and octyl salicylate, octyl methoxycinnamate, homosalate, dioxybenzone, avobenzone, lisadimate, menthyl anthranilate, or octocrylene compound and combinations thereof.

The blocking layer may be comprised of an effective amount of one or more organic blocking material(s) such as methoxycinnamate and octyl salicylate, octyl methoxycinnamate, homosalate, dioxybenzone, avobenzone, lisadimate, menthyl anthranilate, or octocrylene, compounds and combinations thereof. An effective amount is the amount so that the blocking layer 58 can block between about 70% and 100% of the UV light wavelengths between about 100 nm and 500 nm and more preferably light wavelengths between about 200 nm and 400 nm.

In an aspect, the blocking layer may consist essentially of the combination of any two of the following materials: methoxycinnamate and octyl salicylate, octyl methoxycinnamate, homosalate, dioxybenzone, avobenzone, lisadimate, menthyl anthranilate, or octocrylene compound so that preferably the wt % of the blocking layer is between 30 and 70 wt % for at least two of the materials.

In an aspect, the blocking layer may consist essentially of any three or more of the following chemicals methoxycinnamate and octyl salicylate, octyl methoxycinnamate, homosalate, dioxybenzone, avobenzone, lisadimate, menthyl anthranilate, or octocrylene compound so that the wt % of three material in the blocking material component in the blocking layer is more than 20%.

These organic blocking materials may be formed using a spin on deposition process.

E. Radiation Exposure to Cure and Increase Stress in the NMOS Stress Layer Over the NMOS Region

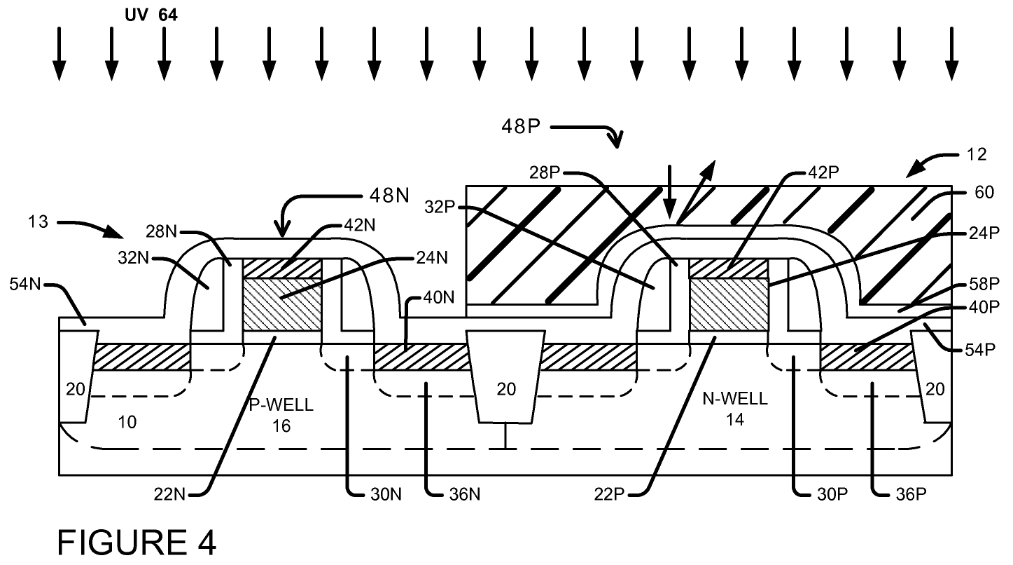

Referring to FIG. 4, we expose (e.g., or cure) the compressive stress layer 54 in the NMOS region 13 to radiation (e.g., UV light or UV radiation) 64 capable of (curing) changing the stress in the stress layer. The blocking layer 58P substantially prevents the compressive stress layer 54P in the PMOS region 12 from being exposed and from substantially changes its' stress. The UV light may penetrate the resist 60 but enough UV light does not penetrate the resist to substantially change the stress of the stress layer 54P. See above. The exposed compressive stress layer 54N in the NMOS region reacts to form a exposed NMOS (e.g., tensile) stress layer 54N. The NMOS stress layer 54N has more tensile stress (a more positive stress value (or less compressive stress)) than the original stress layer 54.

Preferably the exposure substantially changes stress in the stress layer 54 more than about 10%, and more preferably more than about 20% of the stress in the original unexposed stress layer.

Preferably the exposed NMOS tensile stress layer 54N has a tensile stress (less negative stress value) that induces a tensile stress in the NFET 48N channel region.

For example, in CMOS device fabrication, negative-channel MOS device (NMOS) regions 13 are covered with a tensile stressed layer 54N having a more higher (more positive) tensile stress and the positive channel MOS (PMOS) regions 12 are covered with a compressive stressed layer 54P having more negative stress values.

The (compressive) stress layer 54P (no uv exposure) preferably has a (compressive) stress between −2 GPa and −2.5 GPa.

For example, highly (tensile) stress layer 54N (after UV exposure) preferably has a tensile stress between 1 GPa and 1.5 GPa.

The exposure can change the stress of the stress layer at least by 20%. The exposure can change the stress of the stress layer preferably between 25 to 60% of the stress of the unexposed stress layer. (e.g, from compressive −2.5 GPa to −1.0 GPa (1.5/2.6=60%) or e.g. from −2.0 to −1.5 GPa (0.5/2=25%).

An example of an exposure process is a UV exposure using UV light at wavelengths between 200 nm and 400 nm; for a time between 5 and 20 minutes and at a Temperature range between 400 and 480 C.

A suitable ultraviolet radiation source can emit a single ultraviolet wavelength or a broadband of ultraviolet wavelengths. A suitable single wavelength ultraviolet source comprises an excimer ultraviolet source that provides a single ultraviolet wavelength of 172 nm or 222 nm. A suitable broadband source generates ultraviolet radiation having wavelengths of from about 200 to about 400 nm. Such ultraviolet sources can be obtained from Fusion Company, USA or Nordson Company, USA. The stressed silicon nitride material may be exposed to ultraviolet radiation having other wavelengths that are generated by lamps that contain gas that radiates at specific wavelengths when electrically stimulated. For example, suitable ultraviolet lamp may comprise Xe gas, which generates ultraviolet radiation having a wavelength of 172 nm. In other versions, the lamp may comprise other gases having different corresponding wavelengths, for example, mercury lamps radiate at a wavelength of 243 nm, deuterium radiates at a wavelength of 140 nm, and KrCl₂ radiates at a wavelength of 222 nm. Also, in one version, generation of ultraviolet radiation specifically tailored to modify the stress value in the deposited stressed material can be accomplished by introducing a mixture of gases into the lamp, each gas capable of emitting radiation of a characteristic wavelength upon excitation. By varying the relative concentration of the gases, the wavelength content of the output from the radiation source can be selected to simultaneously expose all of the desired wavelengths, thus minimizing the necessary exposure time. The wavelength and intensity of the ultraviolet radiation can be selected to obtain predetermined tensile stress value in the deposited silicon nitride material.

F. UV Increases Tensile Stress in Stressed SIN

Without being limited or bound by this theory, it is thought that that exposure of the deposited silicon nitride (SiN) material to ultraviolet radiation is capable of reducing the hydrogen content of the deposited material (or Si—H bonds), and thereby increasing the tensile stress value of the material. It is believed that exposure to ultraviolet radiation allows replacement of unwanted chemical bonds with more desirable chemical bonds. For example, the wavelength of UV radiation delivered in the exposure may be selected to disrupt unwanted hydrogen bonds, such as the Si—H and N—H bond that absorbs this wavelength. The remaining silicon atom then forms a bond with an available nitrogen atom to form the desired Si—N bonds.

G. Completing the Device

The radiation (e.g., UV) exposure can be an annealing step as the radiation (e.g., UV) exposure can be done at high temperature. For example the UV exposure can be at a temperature between 400 and 480 C for a time between 5 and 20 minutes.

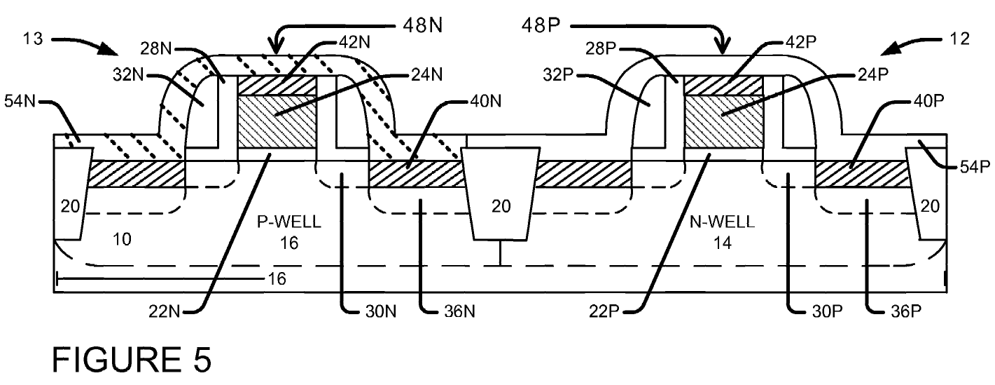

Referring to FIG. 5, we may remove the photoresist 60 and blocking layer 58P using a resist removal process (e.g., ashing) and etch.

The devices can be completed using conventional processes such as forming an interlevel dielectric layer over the transistors and substrate. Contacts and further levels of interconnects and IMD layers can be formed.

H. Non-Limiting Example Embodiments

In the above description numerous specific details are set forth such as flow rates, pressure settings, thicknesses, etc., in order to provide a more thorough understanding of the present invention. Those skilled in the art will realize that power settings, residence times, gas flow rates are equipment specific and will vary from one brand of equipment to another. It will be obvious, however, to one skilled in the art that the present invention may be practiced without these details. In other instances, well known process have not been described in detail in order to not unnecessarily obscure the present invention.

Unless explicitly stated otherwise, each numerical value and range should be interpreted as being approximate as if the word about or approximately preceded the value of the value or range.

Given the variety of embodiments of the present invention just described, the above description and illustrations show not be taken as limiting the scope of the present invention defined by the claims.

While the invention has been particularly shown and described with reference to the preferred embodiments thereof, it will be understood by those skilled in the art that various changes in form and details may be made without departing from the spirit and scope of the invention. It is intended to cover various modifications and similar arrangements and procedures, and the scope of the appended claims therefore should be accorded the broadest interpretation so as to encompass all such modifications and similar arrangements and procedures.

What is claimed is:

1. The method of forming a semiconductor device comprising the steps of:
forming at least a first transistor over a first region of a substrate and forming at least a second transistor over a second region of the substrate;
forming a stress layer over the first and second type transistors;
forming an electromagnetic radiation blocking layer over said second transistor and not over the first transistor;
in an exposure step, exposing the electromagnetic radiation blocking layer over the second transistor and exposing the stress layer over the first transistor to electromagnetic radiation to form a cured stress layer over the first transistor;
the cured stress layer has a different stress than the stress layer;
removing the electromagnetic radiation blocking layer.

2. The method of claim 1 wherein
the first transistor is a NMOS transistor; the NMOS transistor has a NMOS channel;
the second transistor is a PMOS transistor; the PMOS transistor has a PMOS channel;
said stress layer is comprised of silicon nitride;
the cured stress layer has a tensile stress; the cured stress layer over the NMOS transistor induces a tensile stress in the NMOS channel; and
the stress layer has a compressive stress; the stress layer over the PMOS transistor induces a compressive stress in the PMOS channel.

3. The method of claim 1 wherein the stress layer has a compressive stress between −2 GPa and −2.5 GPa; and the cured stress layer has a tensile stress between 1 GPa and 1.5 GPa.

4. The method of claim 1 wherein the exposure step comprises exposing using electromagnetic radiation at a frequency between about 100 and 500 nm.

5. The method of claim 1 wherein the exposure step comprises exposing using electromagnetic radiation at a frequency between about 200 and 400 nm.

6. The method of claim 1 wherein the electromagnetic radiation blocking layer is comprised of material or materials that block between about 70 and 100% electromagnetic radiation at a frequency range between about 200 and 400 nm.

7. The method of claim 1 wherein the exposure step comprising exposing the stress layer to electromagnetic radiation at a dose and frequency capable of substantially changing the stress of said stress layer by at least 20%.

8. The method of claim 1 wherein the blocking layer consists essentially of a material or materials from the group consisting of aluminum oxide, zinc oxide, and titanium oxide and alloys, mixtures and combinations thereof.

9. The method of claim 1 wherein the blocking layer consists essentially of two of the materials from the group consisting of aluminum oxide, zinc oxide, and titanium oxide; each material has a wt % of between about 30 and 70%.

10. The method of claim 1 wherein the blocking layer consists essentially of titanium oxide.

11. The method of claim 1 wherein the blocking layer is comprised of methoxycinnamate and octyl salicylate, octyl methoxycinnamate, homosalate, dioxybenzone, avobenzone, lisadimate, menthyl anthranilate, or octocrylene compound and combinations thereof.

12. The method of claim 1 wherein the electromagnetic radiation blocking layer is comprised of a material selected from the group consisting of aluminum oxide, zinc oxide, and titanium oxide, methoxycinnamate and octyl salicylate, octyl methoxycinnamate, homosalate, dioxybenzone, avobenzone, lisadimate, menthyl anthranilate, octocrylene and their combinations, mixtures or alloys.

13. The method of claim 1 wherein the electromagnetic radiation blocking layer consist of two or more of the materials selected from the group consisting of aluminum oxide, zinc oxide, titanium oxide, methoxycinnamate and octyl salicylate, octyl methoxycinnamate, homosalate, dioxybenzone, avobenzone, lisadimate, menthyl anthranilate, octocrylene; and electromagnetic radiation blocking layer has a wt % of the two of more materials present of at least 20 wt %.

14. The method of forming a semiconductor device comprising the steps of:
forming a NMOS transistor over a NMOS region of a substrate and forming a PMOS transistor over a PMOS region in said substrate; said NMOS transistor has a NMOS channel of said substrate; said PMOS has a PMOS channel in said substrate;
forming a compressive stress layer over the NMOS transistor and PMOS transistor;
forming a UV blocking layer over said PMOS region;
in an exposure step, exposing the compressive stress layer over the NMOS region to ultraviolet light to form a NMOS tensile stress layer over the NMOS region and exposing the UV blocking layer over the PMOS region; the exposure cures the NMOS tensile stress layer to increase the tensile stress; whereby the UV blocking layer blocks the exposure of the compressive stress layer over the PMOS region;
removing said UV blocking layer.

15. The method of claim 14 wherein the compressive stress layer has a compressive stress about between −2 GPa and −2.5 GPa; and the NMOS tensile stress layer has a tensile stress about between 1 GPa and 1.5 GPa.

16. The method of claim 14 wherein the UV blocking layer is comprised of a material or materials from the group consisting of aluminum oxide, zinc oxide, and titanium oxide and combinations thereof.

17. The method of claim 14 wherein the UV blocking layer consists essentially of a two of the materials from the group consisting of aluminum oxide, zinc oxide, and titanium oxide; the two materials have a wt % of between about 30 and 70%.

18. The method of claim 14 wherein the UV blocking layer consists essentially of titanium oxide.

19. The method of claim 14 wherein the UV blocking layer is comprised of methoxycinnamate and octyl salicylate, octyl methoxycinnamate, homosalate, dioxybenzone, avobenzone, lisadimate, menthyl anthranilate, or octocrylene and combinations thereof.

20. The method of claim 14 wherein the UV blocking layer essentially consists of methoxycinnamate and octyl salicylate, octyl methoxycinnamate, homosalate, dioxybenzone, avobenzone, lisadimate, menthyl anthranilate, or octocrylene and combinations thereof.

21. The method of claim 14 wherein the exposure of ultraviolet light is at a dose and frequency capable of changing the stress of the compressive stress layer by at least 20%.

22. The method of claim 14 wherein the UV blocking layer blocks between about 70 and 100% of light in a frequency range between about 200 and 400 nm.

23. The method of claim 14 wherein said compressive stress layer is comprised of silicon nitride.

24. The method of claim 14 wherein said compressive stress layer in the PMOS region induces a compressive stress on the PMOS channel and the NMOS tensile stress layer induces a tensile stress on the NMOS channel.

25. The method of claim 14 wherein the formation of UV blocking layer comprises:
forming the UV blocking layer over substrate;
forming a PMOS mask over PMOS region;
removing the UV blocking layer from over the NMOS region using the PMOS mask as an etch mask; and
before or after the exposure step, removing the PMOS mask.

26. The method of claim 14 wherein the exposure step comprises exposing using electromagnetic radiation at a frequency between about 100 and 500 nm.

27. The method of claim 14 wherein the exposure step comprises exposing using electromagnetic radiation at a frequency between about 200 and 400 nm.
